(19) United States
(12) Patent Application Publication
(10) Pub. No.: US 2008/0143314 A1
(43) Pub. Date: Jun. 19, 2008

(54) Static Electricity Examining Apparatus

(75) Inventor: Falcon Li, Nan Chang City (CN)

Correspondence Address: GROSSMAN, TUCKER, PERREAULT & PFLEGER, PLLC, 55 SOUTH COMMERICAL STREET, MANCHESTER, NH, 03101, US

(73) Assignees: DELTA ELECTRONICS POWER (DONGGUAN) CO., LTD., Dong-Guan City (CN); DELTA ELECTRONICS, INC., Taoyuan Hsien (TW)

(21) Appl. No.: 11/850,097

(22) Filed: Sep. 5, 2007

(30) Foreign Application Priority Data
Dec. 19, 2006 (TW) 095147624

(51) Int. Cl. G01R 19/00

(52) U.S. Cl. 324/76.11

(57) ABSTRACT

A static electricity examining apparatus is provided. The static electricity examining apparatus comprises a static electricity examining ring, a sampling circuit, and a processing circuit. The static electricity examining ring is connected to a user and a ground. The sampling circuit samples a sampling signal from the user. The processing circuit determines the connectivities between the user, the static electricity examining ring, and the ground and generates a processing result.

This application claims priority to Taiwan Patent Application No. 095147624 filed on Dec. 19, 2006, the disclosures of which are incorporated herein by reference in their entirety.

### CROSS-REFERENCES TO RELATED APPLICATIONS

Not applicable.

### BACKGROUND OF THE INVENTION

1. Field of the Invention

The present invention relates to a static electricity examining apparatus; more specifically, it relates to a static electricity examining apparatus that is able to indicate connectivity.

2. Descriptions of the Related Art

Since built up static electricity from a user can damage electronic devices upon touch, grounded static electricity examining rings are required to be worn by the user in order to send the static electricity to the ground. A static electricity examining ring needs to be securely connected to the ground to release the static electricity of the user. Consequently, the user should ensure that the static electricity examining ring is normally connected to the ground. In addition, the connectivity of the grounded static electricity examining ring needs to be examined once or several times a day depending on the circumstances. Unfortunately, this process is time consuming and poses risks to electronic devices touched by the user.

Generally, a user utilizes an examining device to examine whether the static electricity examining ring is well grounded, i.e. whether the static electricity of the user has been released. The user is allowed to work only after the examination, resulting in several examining and waiting periods each day. Furthermore, if the static electricity examining ring fails to function during the examination, static electricity of the user would damage the electronic devices greatly. Thus, it is necessary to develop a static electricity examining apparatus that can thoroughly release static electricity and indicate the examining result to the user.

### SUMMARY OF THE INVENTION

An objective of this invention is to provide a static electricity examining apparatus. The static electricity examining apparatus comprises a static electricity examining ring, a sampling circuit, and a processing circuit. The static electricity examining ring is configured to be connected to a user and a ground. The sampling circuit is configured to sample a static electricity sample signal from the user. The processing circuit is configured to determine connectivity between the user, the static electricity examining ring, and the ground to generate a processing result.

The present invention adopts an automatic static electricity examining apparatus, as opposed to the aforementioned manual examinations. By using the static electricity examining apparatus of the present invention, periodic examination is not required anymore, thereby, reducing the cost. The static electricity examining apparatus monitors the connectivity between the user and the worn static electricity examining ring and completely releases the static electricity of the user. In addition, the apparatus of the present invention can be easily operated and has a low manufacturing cost. A single product line can be equipped with several static electricity examining apparatuses for every several units. Every static electricity examining ring corresponds to a single static electricity examining apparatus independently.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1 illustrates an embodiment of the present invention.

### DESCRIPTION OF THE PREFERRED EMBODIMENT

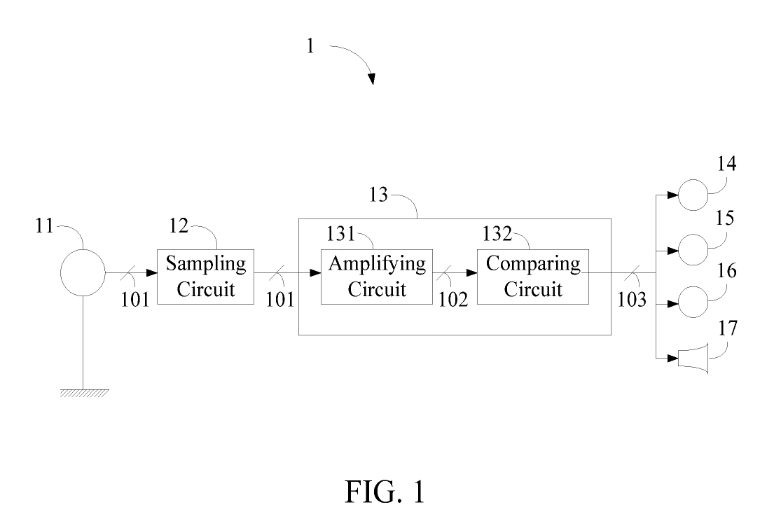

FIG. 1 illustrates an embodiment of the present invention, which is a static electricity examining apparatus 1 comprising a static electricity examining ring 11, a sampling circuit 12, a processing circuit 13, a green light emitting diode (LED) 14, a yellow LED 15, a red LED 16, a speaker 17, a switch (not shown), and a socket (not shown) for the static electricity examining ring 11. The processing circuit 13 comprises an amplifying circuit 131 and a comparing circuit 132.

When a user intends to examine the amount of the static electricity on his or her body, the user wears the static electricity examining ring 11 in a way such that the static electricity examining ring 11 can be connected to the user and a ground. Then, the user turns on the switch to start the static electricity examining apparatus 1. Meanwhile, the sampling circuit 12 is also connected to the static electricity examining ring 11 to sample a static electricity sample signal 101 from the user.

The processing circuit 13, electrically connected to the sampling circuit 12, determines connectivity between the user, the static electricity examining ring, and the ground to generate a processing result, wherein the processing result indicates the connectivity between the user, the static electricity examining ring, and the ground.

In this embodiment, the value of the static electricity sample signal 101 is too small for direct processing, so the amplifying circuit 131 of the processing circuit 13 amplifies the static electricity sample signal 101 to derive a sample related signal 102. The amplifying method executed by the amplifying circuit 131 can be linear or non-linear. It is noted that the amplifying method of the amplifying circuit 131 is not used to limit the scope of the present invention. Next, the comparing circuit 132 of the processing circuit 13 compares the sample related signal 102 with a reference signal to derive the processing result, wherein the reference signal is stored in the comparing circuit 132 and can be adjusted according to the situation. Since the sample related signal 102 is an amplified signal, the comparing circuit 132 can perform the comparison to derive the processing result 103.

The user can then find out his or her connectivity with the static electricity examining ring 11, and the ground from the processing result 103. In this embodiment, the static electricity examining apparatus 1 utilizes three LEDs and an amplifier, such as a speaker, to inform the user of the processing result 103. More specifically, the green LED 14, the yellow LED 15, the red LED 16, and the speaker 17 function in different ways according to the processing result 103 to inform the user of the connectivity of the static electricity examining ring 11. In this embodiment, if the sample related signal 102 is not smaller than the reference signal, the processing result 103 indicates a normal connectivity between the static electricity examining ring 11 and the user by making the green LED 14 light. If the sample related signal 102 is smaller than the reference signal, the processing result 103 indicates an abnormal connectivity between the static electricity examining ring and the user by making the red LED 16 light and making the speaker 17 generate a sound. Furthermore, if the processing result 103 indicates an abnormal connectivity between the static electricity examining ring 11 and the ground, the yellow LED 15 lights up to inform the abnormality. The user may perform suitable operations according to the green LED 14, the yellow LED 15, the red LED 16, and/or the speaker 17. After using the static electricity examining apparatus 1, the user can connect it to the socket (not shown) to fix it.

It is noted that each of the aforementioned green LED 14, yellow LED 15, red LED 16, and the speaker 17 is able to function independently in the static electricity examining apparatus 1. In other words, the static electricity examining apparatus 1 may comprises only one of the green LED 14, the yellow LED 15, the red LED 16, the speaker 17, or the combination thereof to achieve the objective of the present invention.

In addition, the aforementioned green LED 14, yellow LED 15, and red LED 16 may be replaced by LEDs of other colors or by other lighting apparatuses. Similarly, the speaker 17 may be replaced by other sound generating apparatuses.

According to the aforementioned description, the static electricity examining apparatus of the present invention utilizes a sampling circuit and a processing circuit to sample and process the static electricity sample signal from the user. The processing result can be represented in audible and/or in visible ways. For example, the user can find out the connectivity between the user, the static electricity examining ring, and the ground from at least one light indicator (such as the green LED 14, the yellow LED 15, and/or the red LED 16 in the embodiment) and/or from a sound generating apparatus (such as the speaker 17 in the embodiment) in real time and adjust the connectivity accordingly.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A static electricity examining apparatus, comprising:
a static electricity examining ring for being connected to a user and a ground;
a sampling circuit for sampling a static electricity sample signal from the user; and
a processing circuit for determining a connectivity between the user, the static electricity examining ring, and the ground to generate a processing result.

2. The static electricity examining apparatus of claim 1, wherein the processing circuit comprising:
a comparing circuit for comparing a sample related signal with a reference signal to derive the processing result, wherein the sample related signal is related to the static electricity sample signal.

3. The static electricity examining apparatus of claim 2, wherein the processing circuit further comprising:
an amplifying circuit for amplifying the static electricity sample signal to derive the sample related signal.

4. The static electricity examining apparatus of claim 2, further comprising:
a lighting apparatus for lighting to indicate the normal connectivity between the static electricity examining ring and the user, when the processing result indicates that the sample related signal is not smaller than the reference signal.

5. The static electricity examining apparatus of claim 2, further comprising:
a lighting apparatus for lighting to indicate the abnormal connectivity between the static electricity examining ring and the user, when the processing result indicates that the sample related signal is smaller than the reference signal.

6. The static electricity examining apparatus of claim 2, further comprising:
a sound generating apparatus for generating a sound to indicate the abnormal connectivity between the static electricity examining ring and the user, when the processing result indicates that the sample related signal is smaller than the reference signal.

7. The static electricity examining apparatus of claim 1, further comprising:
a lighting apparatus for lighting to indicate a connectivity between the static electricity examining ring and the ground according to the processing result.

8. The static electricity examining apparatus of claim 1, further comprising:
a switch for switching on the static electricity examining apparatus.

9. The static electricity examining apparatus of claim 1, further comprising:
a socket for fixing the static electricity examining ring.

10. The static electricity examining apparatus of claim 3, further comprising:
a first lighting apparatus for lighting to indicate the normal connectivity between the static electricity examining ring and the user, when the processing result indicates that the sample related signal is not smaller than the reference signal;
a second lighting apparatus for lighting to indicate the abnormal connectivity between the static electricity examining ring and the user, when the processing result indicates that the sample related signal is smaller than the reference signal;
a third lighting apparatus for lighting to indicate the abnormal connectivity between the static electricity examining ring and the ground; and
a sound generating apparatus for generating a sound to indicate the abnormal connectivity between the static electricity examining ring and the user, when the processing result indicates that the sample related signal is smaller than the reference signal.
